(19) United States
(12) Patent Application Publication
(10) Pub. No.: US 2012/0107501 A1
(43) Pub. Date: May 3, 2012

(54) COATING DEVICE AND COATING METHOD

(76) Inventors: Tino Harig, Langelsheim (DE); Markus Höfer, Gardessen (DE); Artur Laukart, Braunschweig (DE); Lothar Schäfer, Meine (DE); Markus Armgardt, Braunschweig (DE)

(21) Appl. No.: 13/375,957

(22) PCT Filed: May 13, 2010
(86) PCT No.: PCT/EP10/56624

§ 371 Date: Jan. 10, 2012

(30) Foreign Application Priority Data
Jun. 2, 2009 (DE) 10 2009 023 467.5

(51) Int. Cl. C23C 16/52; C23C 16/50; C23C 16/448; C23C 16/455

(52) U.S. Cl. 427/248.1; 118/724; 118/723 R; 118/712

(57) ABSTRACT

A coating installation containing at least one recipient which can be evacuated and which is provided to receive a substrate, at least one gas supply device which can introduce at least one gaseous precursor into the recipient, and at least one activation device which contains at least one heatable activation element, the end thereof being secured to a securing point on a support element. In the related method, the activation element can be heated by at least one first heating device and at least one second heating device, the first heating device enabling energy to be input in a uniform manner over the longitudinal extension of the activation element and the second heating device enabling energy to be input in a changeable manner over the longitudinal extension of the activation element such that the temperature of the activation element, in at least one longitudinal section, can be brought to over 1300° C. due to the effect of the second heating element.

### BACKGROUND

The invention relates to a coating device, comprising at least one recipient, which can be evacuated and is intended for receiving a substrate, at least one gas supply device, by means of which at least one gaseous precursor can be introduced into the recipient, and at least one activation device, which comprises at least one heatable activation element, the end of which is fastened to a holding element at a fastening point. The invention also relates to a corresponding coating method.

Coating devices of the type mentioned at the beginning are intended according to the prior art for coating a substrate by means of a hot-wire activated chemical vapor deposition. The deposited layers may, for example, comprise carbon, silicon or germanium. Correspondingly, the gaseous precursors may comprise methane, monosilane, monogermanium, ammonia or trimethylsilane.

K. Honda, K. Ohdaira and H. Matsumura, Jpn. J. App. Phys., Vol. 47, No. 5, discloses using a coating device of the type mentioned at the beginning for depositing silicon. For this purpose, silane (SiH₄) is supplied as a precursor by means of the gas supply device. According to the prior art, the precursor is disassociated and activated at the heated tungsten surface of an activation element, so that a layer of silicon can be deposited on a substrate.

However, a disadvantage of the cited prior art is that an undesired reaction of the material of the activation element with the precursor takes place, particularly at the colder clamping points of the activation element. For example, the use of a silane compound as a precursor may lead to the formation of silicide phases on the activation element.

The silicide phases occurring during the reaction generally lead to changes in volume of the activation element, are brittle in comparison with the starting material and cannot withstand such great mechanical forces, and they often exhibit a changed electrical resistance. This has the effect that the activation element is often already destroyed after being in operation for a few hours. For example, the activation element may be used under mechanical prestress in the recipient and rupture under the influence of this mechanical prestress. In order to prevent rupturing of the activation element under mechanical prestress, the prior art proposes flushing the clamping points with an inert gas. Although the prior art does show that the service life is extended to a limited extent, this is still insufficient when performing relatively long coating processes or for carrying out a number of shorter coating processes one directly after the other. Furthermore, the inert gas that is used influences the coating process.

The invention is consequently based on the object of extending the service life of an activation element in a coating device for hot-wire activated chemical vapor deposition without disadvantageously influencing the coating process. The object of the invention is also to increase the stability of the process and/or to simplify the control of the process.

### SUMMARY

According to the invention, it is proposed in a way known per se to introduce a substrate to be coated into a recipient which can be evacuated. The recipient in this case consists, for example, of aluminum, high-grade steel, ceramic and/or glass. At least one gaseous precursor with a predeterminable partial pressure is introduced into the recipient by way of at least one gas supply device. For example, the precursor may comprise methane, silanes, germaniums, ammonia, trimethylsilane, oxygen and/or hydrogen.

For the depositing of a layer, an activation device arranged in the space inside the recipient is used. The activation device comprises a heatable activation element. In addition, the activation device may comprise further components, such as for example holding elements, power supply devices, contact elements or further elements.

In particular, the heating of the activation element may be performed by electrical resistance heating and/or electronic impact heating. In the case of an activation element with a constant cross section, resistance heating by direct current flow brings about a substantially constant input of energy over the longitudinal extent.

The activation element may comprise one or more wires. In addition, the activation element may comprise further geometrical elements, such as plates, sheets or cylinders. A wire may be given a straight configuration or take the form of a spiral or double spiral. The activation element substantially comprises a refractory metal, such as for example molybdenum, niobium, tungsten or tantalum or an alloy of these metals. In addition, the activation element may comprise further chemical elements, which either represent unavoidable impurities or, as an alloying constituent, adapt the properties of the activation element to the desired properties.

At the surface of the activation element, the molecules of the gaseous precursor are split and/or excited. The exitation and/or splitting may comprise a step which proceeds under the influence of a heterogeneous catalyst on the surface of the activation element. The molecules activated in this way or molecules formed reach the surface of the substrate, where they form the desired coating.

The ends of the activation element are fastened to a holding element by means of a fastening point. The fastening may be performed, for example, by clamping, welding or by means of spring tensioning. On account of the increased thermal conductivity and/or heat dissipation of the holding element, if there is a constant energy input over its longitudinal extent then the activation element has a lower temperature in a portion near the fastening point, as compared with a portion at a greater distance from the fastening point. In this case, the temperature of the activation element at the fastening point or near it may fall so far that the material of the activation element undergoes a chemical reaction with the precursor. For example, an activation element comprising tungsten may form a tungsten-silicide phase with a precursor comprising silicon. An activation element comprising tantalum may form a tantalum-carbide phase with a precursor comprising carbon. This may lead to the failure of the activation element at the fastening point or near it.

In order to prevent, or at least delay, the failure of the activation element, it is proposed according to the invention to provide along with the electrical resistance heating or other first heating device, which brings about an energy input that is substantially uniform over the longitudinal extent of the activation element, a second heating device, which brings about an energy input that varies over the longitudinal extent of the activation element. In this way, a longitudinal portion of the activation element that undergoes an increased heat removal, and as a result has a lower temperature, can be additionally heated in order to compensate at least partially for the increased heat removal. The action of the second heating device allows the temperature in a longitudinal portion to be higher than the temperature produced by the effect of the first heating element alone, and in some embodiments of the invention it may be greater than 1300° C., greater than 1500° C., greater than 1800° C. or greater than 2000° C.

Such a longitudinal portion that requires additional heating may be, for example, a portion near a holding element or an electrical contacting location. A portion of the activation element that is located near the holding element is understood according to the invention as meaning a partial area or a partial portion of the activation element in which the temperature of the activation element under uniform energy input falls below the limiting temperature at which the reaction of the material of the activation element with the precursor commences or accelerates. This may be, for example, a temperature of less than 2000° C., less than 1800° C., less than 1500° C. or less than 1300° C. The energy input of the second heating device in a specific portion has the effect of raising the temperature again locally, so that the disadvantageous chemical reaction, for example the formation of a carbide or a silicide, is suppressed.

In a development of the invention, the energy input of the second heating device is confined to a region of the activation element at the fastening point, so that the heat removal by way of the holding element can be compensated. Compensation of the heat removal by way of the holding element is always assumed whenever the temperature of the activation element rises under the influence of the second heating device. At the same time, the temperature of the activation element may be constant over its entire longitudinal extent within predetermined tolerances. The tolerance range may in this case be ±20° C., ±10° C. or ±5° C.

To compensate for the thermal conduction and/or the heat radiation of the holding element, in one embodiment of the invention the second heating device may be designed to bring about an energy input directly into the holding element. In this way, the temperature gradient between the activation element and the holding element is reduced, so that the heat removal from the activation element is reduced as desired. In further embodiments of the invention, the energy input into the holding element may become so great that thermal energy flows from the holding element into the activation element. The ultimate purpose of these measures is to raise the temperature of the activation element over its entire length beyond a threshold value above which a lifetime-shortening formation of carbide or silicide phases is at least slowed down or suppressed.

In one embodiment of the invention, the local heating of the activation element may be performed by the second heating device being designed to introduce radiant energy into the activation element and/or the holding element. In particular, the radiant energy may be provided in the form of infrared radiation. The infrared radiation may be provided, for example, by means of laser light, a spiral-wound filament or a radiant heater.

In a further embodiment of the invention, the second heating device may comprise a device for generating a particle beam. Such a particle beam may be, in particular, an electron beam or ion beam directed onto the fastening point, the holding element or the activation element. In some embodiments of the invention, such a particle beam may have a kinetic energy of approximately 0.5 keV to approximately 10 keV. The amount of charge transported in the particle beam may be between 10 mA and 1000 mA. An ion beam may, in particular, comprise hydrogen ions or noble gas ions. Apart from the local deposition of energy, a particle beam can be additionally used for selectively etching phases formed on the activation element from at least one element of the precursor and at least one element of the activation element, so that a permanent attachment of the undesired phases is prevented or reduced.

Furthermore, the second heating device may comprise a device for generating a plasma. By the action of a plasma, thermal energy can be introduced into the activation element and/or the holding element in a simple way. A plasma may be provided, for example, by way of a hollow cathode glow discharge. Depending on the required energy density and the working pressure of the glow discharge, this may also be confined to a predeterminable spatial region or enhanced by a magnetic field on a case-by-case basis.

A further embodiment of the invention may comprise a device for generating an alternating electric and/or magnetic field. In this way, an eddy current, which brings about local heating, can be induced in the activation element and/or in the holding element. In this case, the second heating device comprises induction heating.

The heating devices mentioned may also be combined with one another. The invention does not teach the presence of precisely one second heating device and precisely one first heating device as a principle for providing a solution.

In order to maximize the lifetime of the activation element, in one embodiment of the invention the second heating device may comprise a control device, which can be fed an actual temperature value in the effective range of the second heating device. The control device may, for example, comprise a P controller, a PI controller or a PID controller. The actual value of the temperature of the activation element may, for example, be measured by means of a pyrometer or a thermocouple. In this way, the temperature of the activation element can be controlled to a predeterminable setpoint value, at which the lifetime of the activation element is at a maximum and/or the coating performance of the coating device is optimized.

Particularly simple control of the second heating device is obtained if the control device can be fed an actual temperature value outside the effective range of the second heating device as a setpoint input. In this case, the second heating device is constantly controlled in such a way that the activation element has a substantially constant temperature over its entire longitudinal extent. A change in the temperature of the activation element brought about by open-loop and/or closed-loop control of the first heating device then leads in an automated manner to an altered setpoint input, and consequently to the automated adaptation of the heating power of the second heating device, so that the power output thereof is adapted to the altered heat removal by way of the holding device.

### BRIEF DESCRIPTION OF THE DRAWINGS

The invention is intended to be explained in more detail below on the basis of exemplary embodiments and figures, without restricting the general concept of the invention. In the figures:

FIG. 1 shows the basic structure of a coating device according to the invention,

FIG. 2 illustrates the structure of a second heating device according to an embodiment of the invention,

FIG. 3 shows an exemplary embodiment of a second heating device, which directs a particle beam onto the area to be heated,

FIG. 4 illustrates the input of thermal energy from a plasma,

FIG. 5 explains the heating of the activation element by means of a laser beam.

### DESCRIPTION OF PREFERRED EMBODIMENTS

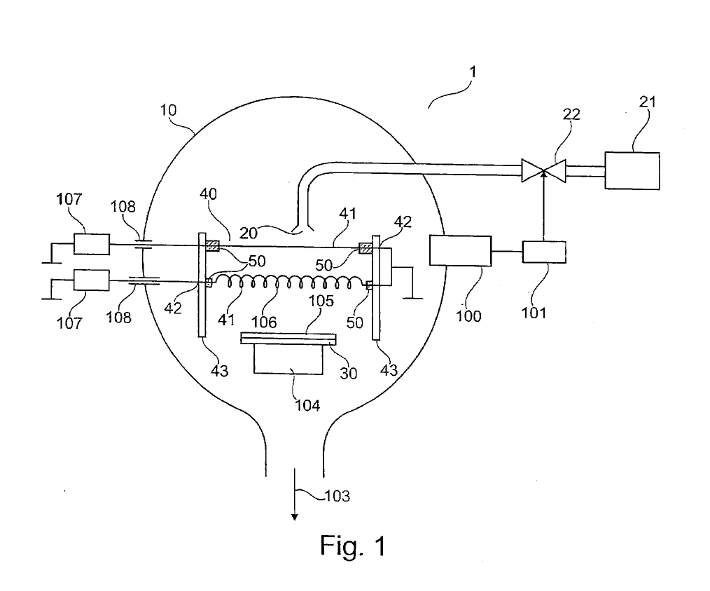

FIG. 1 shows a cross section through a coating device 1. The coating device 1 comprises a recipient 10, which is, for example, produced from high-grade steel, aluminum, glass or a combination of these materials. The recipient 10 is closed off from the surroundings in a substantially airtight manner. A vacuum pump (not represented) may be connected by way of a pump flange 103. For example, the recipient 10 may be evacuated to a pressure of less than 10° mbar, less than 10⁻² mbar or less than 10⁻⁶ mbar.

Inside the recipient 10 there is at least one holding device 104, on which at least one substrate 30 may be mounted. The substrate 30 may, for example, consist of glass, silicon, plastic, ceramic, metal or an alloy. For example, the substrate may be a semiconductor wafer, a pane or a tool. It may have a planar or curved surface. The materials mentioned are only mentioned here by way of example. The invention does not teach the use of a specific substrate as a principle for providing a solution. During the operation of the coating device 1, a coating 105 is deposited on the substrate 30.

The composition of the coating 105 is influenced by the choice of the gaseous precursor. In one embodiment of the invention, the precursor may comprise methane, so that the coating 105 comprises diamond or diamond-like carbon. In another embodiment of the invention, the precursor may comprise monosilane and/or monogermanium, so that the coating comprises crystalline or amorphous silicon and/or germanium.

The gaseous precursor is introduced into the interior of the recipient 10 by way of at least one gas supply device 20. The gas supply device 20 obtains the gaseous precursor from a storage vessel 21. The amount of precursor taken from the storage vessel 21 is influenced by way of a control valve 22. If the coating 105 is made up of a number of different precursors, the storage vessel 21 may comprise a prepared gas mixture, or else a number of gas supply devices may be provided, each introducing a component of the made-up precursor into the recipient 10.

The amount of precursor supplied to the gas supply device 20 by way of the control valve 22 is monitored by way of a control device 101. The control device 101 is supplied with an actual value of a partial or absolute pressure by a measuring device 100.

For the activation of the gaseous precursor, at least one activation device 40 is available. The activation device 40 comprises one or more activation elements 41 with catalytically active surfaces, for example in the form of at least one metal sheet, a tube or a wire. In the embodiment represented in FIG. 1, the activation device 40 comprises as the activation element 41 two wires, which each have a catalytically active surface. For example, the wires 41 may comprise tungsten, molybdenum, niobium and/or tantalum. The wires 41 may be stretched straight or configured by means of a number of turns 106, whereby the active surface of the activation element 41 is further increased.

The activation element 41 is fastened to at least one holding element 43 at least one fastening point 42. The holding element 43 fixes the activation element 41 at a predeterminable position and with a predeterminable mechanical stress.

The activity of the surface of the activation elements 41 is achieved at an elevated temperature in comparison with room temperature. For the heating of the activation elements 41, it is envisaged according to FIG. 1 to connect at least one end of the activation elements 41 to a power source 107 by means of a vacuum-tight leadthrough 108. In this case, the heating of the activation element 41 is performed by resistance heating. If the activation element consists of a homogeneous material and has a uniform cross section, the heating power E introduced along the longitudinal extent x of the activation element is constant:

$$\frac{\partial E}{\partial x} = const .$$

On account of the heat conduction and/or heat radiation of the holding elements 43, the temperature of the activation element 41 decreases from the geometrical center to the periphery if the heating power is substantially constant over the length of the activation element. In this case, a temperature at which the material of the activation element 41 is reacted with the gaseous precursor to form undesired phases, for example carbides and/or silicides, may be established near the fastening point 42. This may lead to alteration of the mechanical and/or electrical properties of the activation element 41, and consequently to damage thereto. With the higher temperature being established at a greater distance from the holding element, the precursor is on the other hand excited and/or disassociated and does not enter into a bond with the activation element 41, or only to a slight extent, so that the damage there is less.

In order to compensate for this drop in temperature, it is proposed according to the invention to use a second heating device 50, which additionally heats either the holding device 43 or the activation element 41 in the region of the fastening point 42. In this way, the temperature of the activation element 41 can be raised over its entire length to a value at which the processes leading to the phase transformation of the activation element are prevented or slowed down. At least the processes leading to the phase transformation proceed at approximately the same rate over the entire length of the activation element, so that the lifetime of the activation element 40 is no longer limited by the lifetime of a small portion near the fastening point 42. With appropriate design of the second heating device 50, it can be achieved that the activation element 41 has a substantially constant temperature between the holding devices 43.

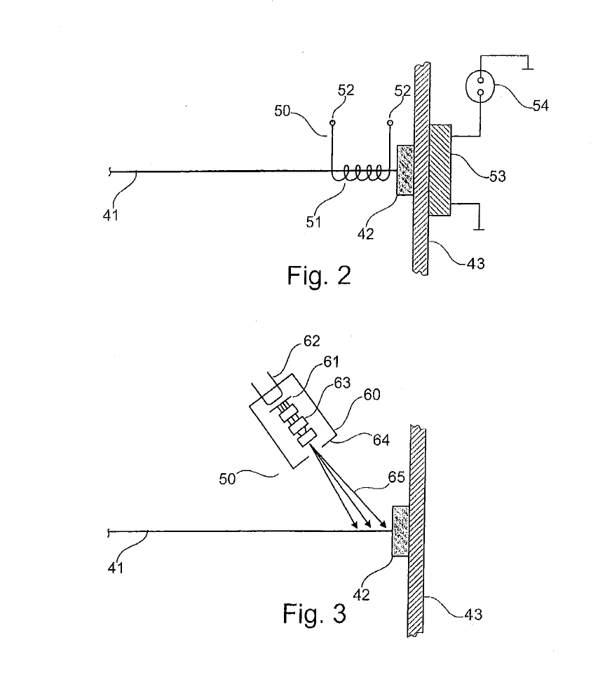

FIG. 2 shows an exemplary embodiment of a second heating device 50. In the right part of the image of FIG. 2, a section through part of a holding device 43 is represented. On the holding device 43 there is a fastening point 42, at which an activation element 41 is connected to the holding device 43. A heating power that is substantially constant over the length of the activation element 41 is introduced into the activation element 41 by means of a first heating device. The heat removal from the activation element takes place over the longitudinal extent thereof substantially by radiation and convection. In the peripheral region, the activation element 41 additionally undergoes an additional heat loss through heat conduction by way of the holding device 43. This has the effect that the temperature of the activation element 41 falls from the middle thereof toward the fastening point 42.

In order to compensate for the drop in temperature near the fastening point 42, a second heating device 50 is provided. According to FIG. 2, the heating device 50 comprises, a spiral-wound filament 51, which surrounds the activation element 41. The spiral-wound filament 51 may be connected to a DC or AC voltage source (not represented) by way of connecting contacts 52.

The spiral-wound filament 51 may input thermal energy into the activation element 41 by way of a number of mechanisms. For example, the spiral-wound filament 51 may be brought to an elevated temperature by direct current flow, so that it emits infrared radiation, which can be absorbed by the activation element 41. Furthermore, the spiral-wound filament 51 may be operated with an AC voltage source, so that an alternating electromagnetic field forms inside the spiral 51. This leads to the induction of an alternating current in the activation element 41, so that the current flowing in the activation element 41 is increased locally. As a result, additional thermal energy is deposited in the activation element 41 in the effective range of the spiral-wound filament 51. Finally, a potential difference may be applied between the spiral-wound filament 51 and the activation element 41, so that electrons released by thermionic emission from the spiral-wound filament 51 are accelerated onto the activation element 41. This leads to electronic impact heating of the activation element 41. In some embodiments of the invention, a number of the effects mentioned may be combined. On a case-by-case basis, however, the spiral-wound filament 51 may also be connected such that a thermal energy input into the activation element 41 only takes place by a single physical effect.

In addition or as an alternative, an electrical heating resistor 53 may be fastened to the holding device 43. The heating resistor 53 may be fastened to the holding device 43, for example, by soldering or brazing, clamping or welding. To improve the thermal contact between the holding device 43 and the heating resistor 53, an intermediate layer of a ductile metal may be used, for example gold or indium.

The electrical heating resistor 53 is supplied with electrical energy by means of a DC or AC voltage source 54. In the heating resistor 53, the electrical energy is converted into thermal energy and fed to the holding element 43. This leads to a smaller temperature gradient between the holding element 43 and the activation element 41, so that the temperature of the activation element 41 rises as a result of the reduced heat removal by way of the holding element 43. If the temperature of the holding element 43 exceeds the temperature of the activation element 41, there is a heat input from the holding element 43 into the activation element 41, so that the temperature of the latter likewise rises in the region of the fastening point 42.

FIG. 3 shows a further embodiment of the second heating device 50 proposed according to the invention. The heating device 50 comprises an electron gun 60. Inside the electron gun 60 there is an indirectly heated cathode 61, which is heated by way of a heating spiral 62 to a temperature at which a thermionic emission takes place.

The electron beam 65 generated by the cathode 61 is focused and/or defocused by way of one or more electrostatic lenses and leaves the electron gun 60 by way of the exit aperture 64. The optical system formed by the exit aperture 64 and the electrostatic lenses 63 can be used for the purpose of bringing the beam profile of the electron beam 65 into a form which is adapted to the area to be heated. The electron beam 65 is finally absorbed by the area to be heated. In the example according to FIG. 3, this is a partial area of the activation element 41 adjacent the fastening point 42. The energy input into the activation element 41 by the electron gun 60 is determined by the absorbed number of particles, i.e. the electron stream and the kinetic energy thereof. To control the energy input, therefore, either the temperature of the cathode 61 and/or the acceleration voltage of the lens system 63 may be adapted.

In the same way as described above for an electron beam, thermal energy may also be input into the activation element 41, the fastening point 42 or the holding device 43 by an ion beam.

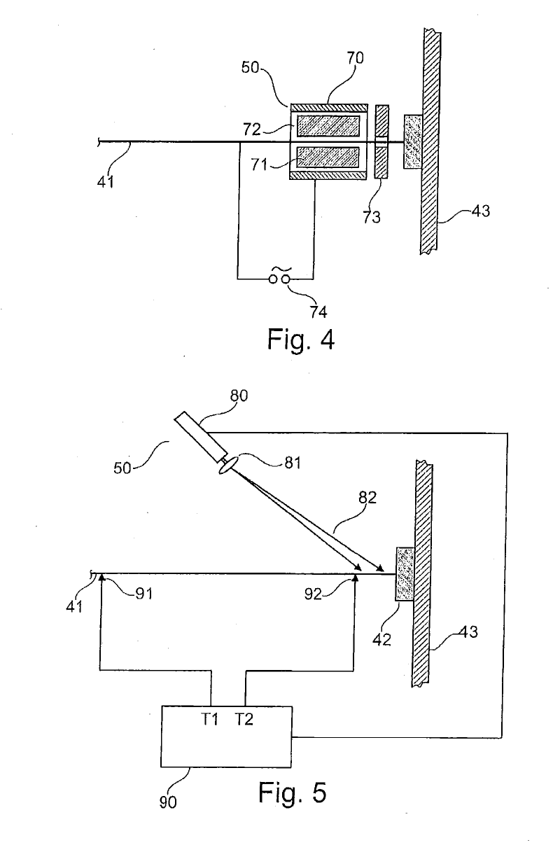

FIG. 4 shows an exemplary embodiment of plasma heating of the activation element 41.

FIG. 4 shows once again a cross section through the heating element 43. The partial portion of the activation element 41 that is to be heated is located in the interior space 72 of a hollow cathode 70. Since the interior space 72 of the hollow cathode 70 is open to the recipient, the same pressure as in the recipient 10 prevails in the interior space 72. By applying an AC voltage from a voltage source 74 to the hollow cathode 70 and the activation element 41 running through the hollow cathode, there forms in the interior space 72 an alternating electric field, which leads to the ignition of a plasma 71. The plasma 71 acts on a partial portion of the activation element 41, thermal energy being deposited in the activation element 41. The control of the thermal energy introduced from the plasma 71 may be performed by controlling the AC voltage source 74. In some embodiments of the invention, the frequency of the AC voltage source 74 may be approximately 100 kHz to approximately 14 MHz.

In order to confine the plasma 71 to a predeterminable region in the interior space 72 of the hollow cathode 70, in some embodiments of the invention an optional magnetic field generating device 73 may be used. The magnetic field generating device 73 may, for example, comprise at least one permanent magnet and/or at least one electromagnetic coil. The magnetic field generating device 73 brings about a magnetic confinement of the plasma 71, so that it does not disturb the coating process proceeding in the recipient 10, or to a lesser extent.

By a further gas supply device, which opens out in the interior space 72 of the hollow cathode 70, it may be provided in a development of the embodiment that not only does the plasma 71 input thermal energy into the activation element 41, but additionally a protective layer is deposited onto the activation element 41 from the plasma 71. Furthermore, the plasma 71 may be intended for the purpose of removing undesired phases, such as for example carbides or silicides, from the activation element 41 by plasma etching, so that the lifetime thereof is additionally increased. Finally, the plasma may be designed for the purpose of reacting with penetrating precursors, so that the reaction products at least react more slowly with the activation element 41.

FIG. 5 shows a further exemplary embodiment of a second heating device 50. The heating device 50 according to FIG. 5 comprises a laser 80. In particular, the laser 80 is designed for the purpose of emitting an infrared light beam 82, which is subsequently absorbed by the activation element 41 and/or the fastening point 42 and/or the holding device 43. To adapt the size of the beam spot of the laser beam 82, an optional lens system 81 may be available. The selective heating of the activation element 41 or the holding element 43 by means of a laser beam 82 is distinguished by particularly short response times, whereby the heat input can be quickly adapted to changing conditions.

To control the intensity of the beam emitted by the laser 80, a control device 90 is available. The control device 90 may, for example, comprise a P controller, a PI controller or a PID controller. The control device 90 may be configured as an electronic circuit, for example using one or more operational amplifiers. In an alternative embodiment, the control device 90 may comprise a microprocessor, on which the control algorithm is configured in the form of software.

In the exemplary embodiment according to FIG. 5, the control device 90 is connected to two temperature sensors 91 and 92. The temperature sensors 91 and 92 may, for example, each comprise a thermocouple, a device for measuring an electrical resistance or a pyrometer. The temperature sensor 91 is intended for the purpose of measuring a temperature T1 in a longitudinal portion of the activation element 41 that is predominantly cooled by radiation and/or convection and largely uninfluenced by the heat removal through the holding element 43. The temperature sensor 92 is intended for the purpose of measuring the temperature T2 of the activation element 41 in the effective range of the second heating device 50. If the heating device 50 is switched off, the temperature T2 will usually be lower than the temperature T1 as a result of the additional heat loss by way of the holding device 43.

The control device 90 then uses the temperature T1 as a setpoint input and the temperature T2 as an actual value. Thereafter, the heating power of the second heating device 50 is controlled in such a way that the two temperatures are equalized to within a predeterminable tolerance range. In this way, the second heating device 50 deposits an amount of energy in the activation element 41 that compensates for the additional heat removal by way of the holding element 43. It goes without saying that the control device 90 may be combined with any of the variants of the second heating device 50 that are represented in FIGS. 2-5.

The invention does not disclose the use of a single second heating device 50 as a principle for providing a solution. Rather, the features represented in FIGS. 2-5 with respect to the second heating device 50 may be combined in order in this way to obtain further embodiments of the invention. Therefore, the above description should not be regarded as restrictive, but as explanatory. The claims which follow should be understood as meaning that a feature which is mentioned is present in at least one embodiment of the invention. This does not exclude the presence of further features. Wherever the claims define “first” and “second” features, this designation serves for distinguishing between two identical features, without giving them any priority.

1.-19. (canceled)

20. A coating device, comprising at least one recipient, which is adapted to be evacuated and which is adapted to receive a substrate, at least one gas supply device, being adapted to introduce at least one gaseous precursor into the recipient, and at least one activation device, comprising at least one heatable activation element, the end of which is fastened to a holding element at a fastening point, wherein the activation element is adapted to be heated by a first heating device and at least one second heating device, wherein the first heating device is adapted to cause a uniform energy input along the longitudinal extent of the activation element and the second heating device is adapted to cause a varying energy input along the longitudinal extent of the activation element, so that, under the action of the second heating device, the temperature of the activation element in at least one longitudinal portion of the activation element can be brought above 1300° C.

21. The coating device according to claim 20, wherein the first heating device comprises resistance heating.

22. The coating device according to claim 20, wherein the energy input of the second heating device can be restricted to a region of the activation element at the fastening point, so that the heat removal by way of the holding element can be compensated at least partly.

23. The coating device according to claim 20, wherein the second heating device is adapted to deposit a thermal energy into the holding element.

24. The coating device according to claim 20, wherein the second heating device is designed to deposit radiant energy into the activation element and/or the holding element.

25. The coating device according to claim 20, wherein the second heating device comprises a device for generating a particle beam or wherein the second heating device comprises a device for generating a plasma.

26. The coating device according to claim 20, wherein the second heating device comprises a device for generating an alternating electric and/or magnetic field.

27. The coating device according to claim 20, wherein the second heating device comprises a control device, which is adapted to determine an actual temperature value in the active region of the second heating device.

28. The coating device according to claim 27, wherein the control device is adapted to determine further an actual temperature value outside the active region of the second heating device.

29. A coating device, comprising at least one recipient, which is adapted to be evacuated and which is adapted to receive a substrate, at least one gas supply device, being adapted to introduce at least one gaseous precursor into the recipient, and at least one activation device, comprising at least one heatable activation element, the end of which is fastened to a holding element at a fastening point, wherein the activation element is adapted to be heated by a first heating device and at least one second heating device, wherein the first heating device is adapted to cause a uniform energy input along the longitudinal extent of the activation element and the second heating device is adapted to cause a varying energy input along the longitudinal extent of the activation element, wherein the second heating device is designed to deposit radiant energy into the activation element and/or the holding element.

30. The coating device according to claim 29, wherein the second heating device comprises a device for generating a particle beam or wherein the second heating device comprises a device for generating a plasma or wherein the second heating device comprises a device for generating an alternating electric and/or magnetic field.

31. A method for producing a coating of a substrate comprising:
Introducing the substrate into a recipient
Evacuating the recipient
Introducing at least one gaseous precursor into the recipient by way of at least one gas supply device
Activating said precursor by means of at least one activation device, the activation device comprising at least one heated activation element, the end of which is fastened to a holding element at a fastening point, wherein
the activation element is heated by a first heating device and at least one second heating device, wherein
the first heating device causes a uniform energy input along the longitudinal extent of the activation element and the second heating device causes a varying energy input along the longitudinal extent of the activation element, so that, under the action of the second heating device, the temperature of the activation element in at least one longitudinal portion of the activation element rises to 1300° C. or higher.

32. The method according to claim 31, wherein an electric current flows through the activation element.

33. The method according to claim 31, wherein the energy input of the second heating device is restricted to a longitudinal portion of the activation element at the fastening point, so that the heat removal by way of the holding element is at least partly compensated.

34. The method according to claim 31, wherein the second heating device deposits thermal energy into the holding element.

35. The method according to claim 31, wherein electromagnetic radiation is deposited into any of the activation element or the holding element.

36. The method according to claim 31, wherein a particle beam is directed onto any of the activation element or the holding element.

37. The method according to claim 31, wherein a plasma acts on any of the activation element or the holding element.

38. The method according to claim 31, wherein an alternating electric and/or magnetic field acts on any of the activation element or the holding element.

39. The method according to claim 31, wherein the energy input of the second heating device is controlled, so that the temperature of the activation element is substantially constant along its longitudinal extent.
